(19) United States
(12) Patent Application Publication
(10) Pub. No.: US 2006/0210783 A1
(43) Pub. Date: Sep. 21, 2006

(54) Coated article with anti-reflective coating and method of making same

(76) Inventors: Thomas A. Seder, Northville, MI (US); Thomas J. Taylor, Northville, MI (US)

Correspondence Address: NIXON & VANDERHYE, PC, 901 NORTH GLEBE ROAD, 11TH FLOOR, ARLINGTON, VA, 22203, US

(21) Appl. No.: 11/083,074

(22) Filed: Mar. 18, 2005

(51) Int. Cl. B32B 17/06; C23C 14/00; H05H 1/26

(52) U.S. Cl. 428/212; 428/426; 427/523; 427/446

(57) ABSTRACT

A substrate is treated so as to improve anti-reflection (AR) characteristics of a resulting coated article. In certain example embodiments, a glass substrate may be treated via ion implantation to increase a refractive index (n) value in a surface region thereof. In other example embodiments, an index-graded coating (single or multi-layer) may be formed on the substrate. In both embodiments, an AR coating

Certain example embodiments of this invention relate to coated articles which include an anti-reflective coating on a glass substrate, and methods of making the same. Such coated articles may be used in the context of, for example and without limitation, storefront windows, fireplace door/window glass, picture frame glass, display glass, or in any other suitable application(s).

### BACKGROUND OF THE INVENTION

The need for anti-reflective (AR) coatings on glass substrates is known in the art. For example, see U.S. Pat. No. 5,948,131.

Reflections in optical systems occur due to index of refraction (n) discontinuities. Complex layer structures are often deposited on glass substrates in an attempt to compensate for such index discontinuities.

Glass typically has an index of refraction of about 1.46 (i.e., n=1.46), and that of air is about 1.0 Thus, given a glass substrate having an index (n) of 1.46 and adjacent air having an index (n) of 1.0, the most desirable index (n) for an AR coating can be calculated as follows:
n=square root of (1.46×1.0)=1.23

Unfortunately, durable coating materials having an index of refraction (n) of 1.23 are not typically available. Because durable AR coatings having an index of about 1.23 are not typically available, those in the art have tried to provide for AR characteristics in other manners. For example, see U.S. Pat. Nos. 5,948,131, 4,440,882, and 6,692,832. However, the techniques used in these patents are often not desirable, as they tend to be too expensive and/or burdensome.

In view of the above, it will be apparent to those of skill in the art that there exists a need in the art for coated articles with improved AR characteristics, and methods of making the same.

### BRIEF SUMMARY OF EXAMPLES OF THE INVENTION

In certain example embodiments of this invention, improved anti-reflective (AR) characteristics are achieved by modifying the glass substrate itself. Consider the below equation which, when an AR type coating is desired, can be used to calculate an approximate desired refractive index of a coating (n_{c}) to be applied to a glass substrate (where n_{g} is the refractive index of glass and nₐ is the refractive index of air):
n_{c}=square root of (n_{g}×nₐ)

The refractive index of air is typically 1.0 (i.e., nₐ=1.0). Moreover, as explained above, durable AR coating materials having low index values such as about 1.23 are not typically available. Thus, in certain example embodiments of this invention, the refractive index of the glass substrate (i.e., n_{g}) is varied. For example, a surface portion of the glass substrate may be implanted with ions (e.g., argon and/or nitrogen ions) from an ion source(s). This ion implantation can be performed in a manner which causes at least part of the surface portion of the glass substrate to realize a higher refractive index value (e.g., from about 1.55 to 2.5, more preferably from about 1.75 to 2.25, and even more preferably from about 1.8 to 2.2). Consider, for example and without limitation, a situation where the ion implantation is performed in a manner which causes the outer surface of the glass substrate to realize a refractive index of 2.13 (i.e., n_{g}=2.13). This would result in the following desired refractive index of a coating (n_{c}) to be applied to the glass substrate:
n_{c}=square root of (2.13×1.0)=1.46

A coating material such as silicon oxide (e.g., SiO₂)or the like can be formed so as to have a refractive index of about 1.46-1.5; this value matches or substantially matches the desired n_{c}. Thus, when such a coating is applied to an ion implanted surface of a glass substrate as discussed above, the resulting AR characteristics of the coated article are good and visible reflection can be reduced. Of course, these values and materials are not intended to be limiting and other values and/or materials may instead be used.

In certain example embodiments of this invention, the ion implantation may be performed in a manner which causes the index of refraction (n) at the surface area or portion of the glass substrate to be graded, so as to progressively increase toward the surface of the glass substrate on which the AR coating is to be applied.

In other example embodiments of this invention, a coating with a graded refractive index can be applied to a glass substrate via combustion CVD (CCVD). The use of a CCVD deposited coating may be used in combination with or separate from embodiments where the glass surface is ion implanted.

In certain example embodiments of this invention, method of making a coated article, the method comprising: providing a glass substrate having an index of refraction (n) of from about 1.4 to 1.5; implanting ions into a surface region of the glass substrate in a manner sufficient to cause an index of refraction at a surface of the glass substrate to increase to a value of from about 1.55 to 2.5, thus forming a glass substrate having a surface region that is ion implanted; and forming an anti-reflective coating on the ion implanted surface region of the glass substrate.

In other example embodiments of this invention, there is provided a method of making a coated article, the method comprising: providing a glass substrate; using flame pyrolysis to form a layer on the glass substrate, wherein the layer formed using flame pyrolysis is characterized by one or more of: (a) the layer includes more Sn at a location in the layer further from the glass substrate than at a location in the layer closer to the glass substrate, and (b) the layer includes less Si at a location in the layer further from the glass substrate than at a location in the layer closer to the glass substrate.

### BRIEF DESCRIPTION OF THE DRAWINGS

FIG. 1 is a flowchart illustrating certain example steps performed according to an example embodiment of this invention.

FIG. 2 is a cross sectional view of a coated article according to an example embodiment of this invention, which may be made in accordance with the steps shown in FIG. 1.

FIG. 3 is a cross sectional view of an example glass substrate that may be used in the context of any of FIGS. 1, 2 or 6.

FIG. 4 is a cross sectional view of an example ion source that may be used in certain example embodiments of this invention.

FIG. 5 is a perspective view of the ion source of FIG. 4.

FIG. 6 is a schematic diagram illustrating how a coated article may be made according to another example embodiment of this invention in which CCVD may be utilized.

FIG. 7 is a schematic diagram illustrating how a coated article may be made according to another example embodiment of this invention in which sputtering may be utilized.

FIG. 8 is a schematic diagram illustrating how a coated article may be made according to another example embodiment of this invention in which sputtering may be utilized.

FIG. 9 is a schematic diagram illustrating how a coated article may be made according to another example embodiment of this invention in which sputtering may be utilized.

### DETAILED DESCRIPTION OF EXAMPLE EMBODIMENTS OF THE INVENTION

Referring now more particularly to the accompanying drawings in which like reference numerals indicate like parts throughout the several views.

Certain example embodiments of this invention relate to coated articles which include an anti-reflective coating on a glass substrate, and methods of making the same. Such coated articles may be used in the context of, for example and without limitation, storefront windows, fireplace door/window glass, picture frame glass, architectural windows, residential windows, display glass, or in any other suitable application(s). An AR coating of a single layer is preferred in certain example embodiments, although a multi-layer AR coating may be used in other embodiments of this invention.

In certain example embodiments of this invention, improved anti-reflective (AR) characteristics are achieved by modifying the glass substrate itself. Consider the below equation which, when an AR type coating is desired, can be used to calculate an approximate desired refractive index of a coating (n_{c}) to be applied to a glass substrate (where n_{g} is the refractive index of glass and nₐ is the refractive index of air):
n_{c}=square root of (n_{g}×nₐ)

The refractive index of air is typically 1.0 (i.e., nₐ=1.0). Moreover, as explained above, durable AR coating materials having low index values such as about 1.23 are not typically available. Thus, in certain example embodiments of this invention, the refractive index of the glass substrate (i.e., n_{g}) is varied. For example, a surface portion of the glass substrate may be implanted with ions (e.g., argon and/or nitrogen ions) from an ion source(s). This ion implantation can be performed in a manner which causes at least part of the surface portion of the glass substrate to realize a higher refractive index value (e.g., from about 1.55 to 2.5, more preferably from about 1.75 to 2.25, and even more preferably from about 1.8 to 2.2). Consider, for example and without limitation, a situation where the ion implantation is performed in a manner which causes the outer surface of the glass substrate to realize a refractive index of 2.13 (i.e., n_{g}=2.13). This would result in the following desired refractive index of a coating (n_{c}) to be applied to the glass substrate:
n_{c}=square root of (2.13×1.0)=1.46
A dielectric coating material such as silicon oxide (e.g., SiO₂)or the like can be formed so as to have a refractive index of about 1.46-1.5; this value matches or substantially matches the desired n_{c}. Thus, when such a coating is applied to an ion implanted surface of a glass substrate as discussed above, the resulting AR characteristics of the coated article are good and visible reflection can be reduced. Of course, these values and materials are not intended to be limiting and other values and/or materials may instead be used. In certain example embodiments of this invention, the coating is designed so as to have an index of refraction value (n) which differs by no more than 0.25 (more preferably by no more than 0.2, more preferably by no more than 0.15, even more preferably by no more than 0.10, and most preferably by no more than 0.05) from n_{c} (where n_{c}=square root of (n_{g}×nₐ)).

Consider another example as follows. Ion implantation is performed in a manner which causes the outer surface of the glass substrate to realize a refractive index of 2.35 (i.e., n_{g}=2.35). This would result in the following desired refractive index of a coating (n_{c}) to be applied to the glass substrate:
n_{c}=square root of (2.35×1.0)=1.53
A coating material 2 such as silicon oxide and/or silicon oxynitride, or the like can be formed so as to have a refractive index of about 1.5 to 1.6; this value matching or substantially matching the desired n_{c} of 1.53. Thus, when such a coating is applied to an ion implanted surface of a glass substrate as discussed above, the resulting AR characteristics of the coated article are good and visible reflection can be reduced.

Consider yet another example as follows. Ion implantation is performed in a manner which causes the outer surface of the glass substrate to realize a refractive index of 1.88 which is about a 25% increase (i.e., n_{g}=1.88). This would result in the following desired refractive index of a coating (n_{c}) to be applied to the glass substrate:
n_{c}=square root of (1.88×1.0)=1.37
A single-layer coating 2 of a material such as MgF₂ and/or CaF₂ has in index (n) close to this desired value; so that such a single layer coating 2 could match or substantially match the desired n_{c} of 1.37. For example, a coating of or including MgF₂ may be applied via a sol-gel technique. Thus, when such a coating is applied to an ion implanted surface of a glass substrate as discussed above, the resulting AR characteristics of the coated article are good and visible reflection can be reduced.

In certain example embodiments of this invention, the ion implantation may be performed in a manner which causes the index of refraction (n) at the surface area or portion of the glass substrate to be graded, so as to progressively increase toward the surface of the glass substrate on which the AR coating is to be applied.

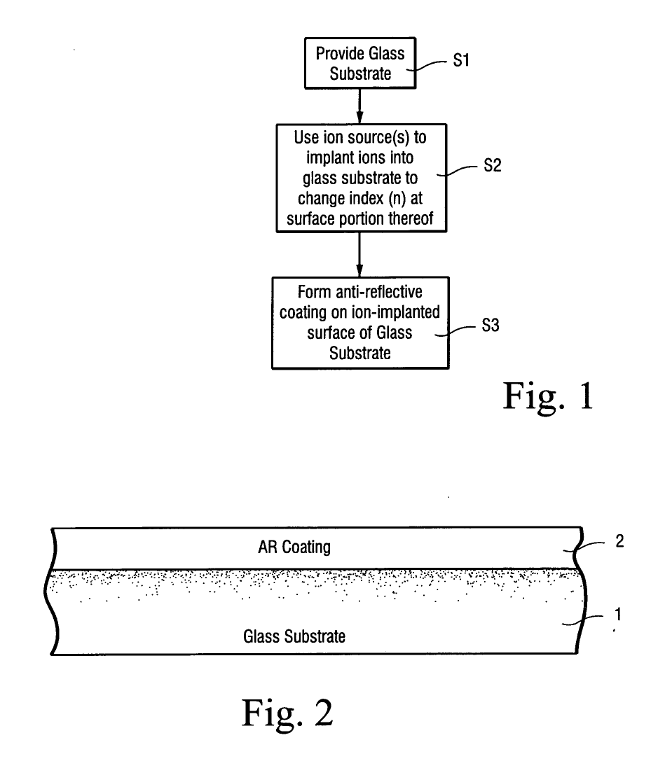

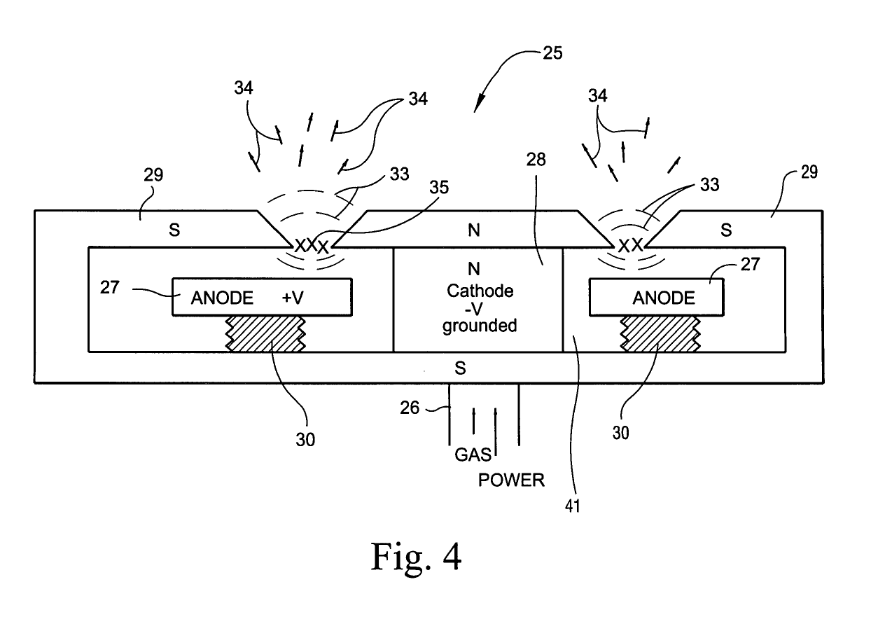

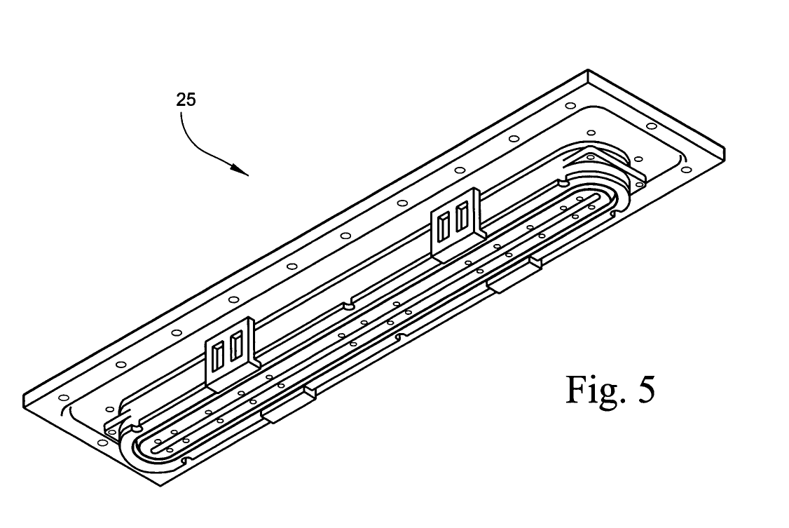

FIG. 1 is a flowchart illustrating certain example steps which may be performed in making a coated article according to an example embodiment of this invention. FIG. 2 is a cross sectional view of a resulting coated article. FIGS. 4-5 illustrate an example ion source that may be used in making the coated article of FIG. 1.

Referring to FIGS. 1-2 and 4-5, in step S1, a glass substrate 1 is provided. The glass substrate 1 may be, for example, a flat float glass (soda-lime-silica based glass) substrate or a borosilicate glass substrate. Prior to subjecting the glass substrate 1 to an ion beam, the glass substrate typically has an index of refraction (n) of from about 1.4 to 1.5, more preferably from about 1.44 to 1.48, and about 1.46 as an example. Then, in step S2, one or more ion sources 25 are used to implant ions into a surface portion or region of the glass substrate 1. It has been found that argon and/or nitrogen ions (and/or other ions discussed herein) are particularly good at causing the index (n) at the surface portion of the glass substrate 1 to increase. This ion implantation is typically done without forming a new layer on the glass substrate. In certain example embodiments of this invention, the ion source(s) may be located on a float line to treat the glass as it is manufactured (e.g., at an end portion thereof).

The index (n) of a material is determined by the density and the polarizability of the material. The ion implantation or certain types of ions (e.g., one or more of Ar ions, N ions, Ce ions, Ti ions, Ta ions, Sn ions, Al ions, Cr ions, Fe ions, Mn ions, Cu ions and/or Mg ions) into the surface region of the glass substrate 1 causes the density of the glass substrate to increase in this area. During the process, these atoms would become ionized and it can be envisioned that other benefits could be obtained (e.g., by using Ce or Va ions, attenuation of transmitted UV could be obtained). With respect to certain ions: for example, Ar ions may primarily cause density of the surface region of the glass substrate to increase, whereas nitrogen (N) ions may cause both the density of the region to increase and the polarizability to increase thereby causing the index of refraction (n) to increase for these reason(s). The introduction of N ions may cause silicon oxynitride to form at the glass surface region, whereas the introduction of Mg ions may cause MgO to form at the glass surface region, leading to increased indices (n).

After the surface region of the glass substrate 1 has been ion implanted in step S2, an AR coating 2 is applied to the ion treated surface of the substrate 1 in step S3 (see also FIG. 2). The AR coating 2 may be a single dielectric layer coating, or may be a multiple layer coating (where on or more of the layers is/are dielectric) in different embodiments of this invention. For example, the AR coating 2 may be of or include a layer of silicon oxide (e.g., SiO₂), a layer of silicon oxynitride, and/or a layer of tin oxide in certain example embodiments of this invention. AR coating 2 may be deposited via sputtering, flame pyrolysis, sol-gel, or in any other suitable manner. Other layers may optionally be positioned above the AR coating 2 in certain example embodiments of this invention. It is preferable that the layer of coating adjacent and contacting the glass substrate 1 has an index of refraction of no greater than 1.75, more preferably no greater than 1.65, and most preferably no greater than 1.55. Layers comprising silicon oxide are especially advantageous in this respect for coating 2, since silicon oxide tends to have a low index of refraction value.

FIGS. 4-5 illustrate an exemplary linear or direct ion beam source 25 which may be used to perform the ion implantation in step S2. Ion beam source (or ion source) 25 includes gas/power inlet 26, racetrack-shaped anode 27, grounded cathode magnet portion 28, cathode 29, magnet poles, and insulators 30. An electric gap is defined between the anode 27 and the cathode 29. A 3 kV or any other suitable DC power supply may be used for source 25 in example embodiments. The gas(es) discussed herein (e.g., argon and/or nitrogen gas) for use in the ion source during the ion beam implantation of the glass substrate may be introduced into the source via gas inlet 26, or via any other suitable location. Ion beam source 25 is based upon a known gridless ion source design. The linear source may include a linear shell (which is the cathode and grounded) inside of which lies a concentric anode (which is at a positive potential). This geometry of cathode-anode and magnetic field 33 may give rise to a close drift condition. Feedstock gases (e.g., nitrogen, argon, a mixture of nitrogen and argon, etc.) may be fed through the cavity 41 between the anode 27 and cathode 29. The electrical energy between the anode and cathode cracks the gas to produce a plasma within the source. The ions 34 (e.g., nitrogen and/or argon ions) are expelled out (e.g., due to the gas in the source) and directed toward the substrate to be ion beam treated in the form of an ion beam. The ion beam may be diffused, collimated, or focused. Example ions 34 output from the source are shown in FIG. 4. A linear source as long as 0.5 to 4 meters may be made and used in certain example instances, although sources of different lengths are anticipated in different embodiments of this invention. Electron layer 35 is shown in FIG. 4 and completes the circuit thereby permitting the ion beam source to function properly. Example but non-limiting ion sources that may be used are disclosed in U.S. Pat. Nos. 6,303,226, 6,359,388, and/or 2004/0067363, all of which are hereby incorporated herein by reference. One or more of such sources may be used to ion treat the substrate 1.

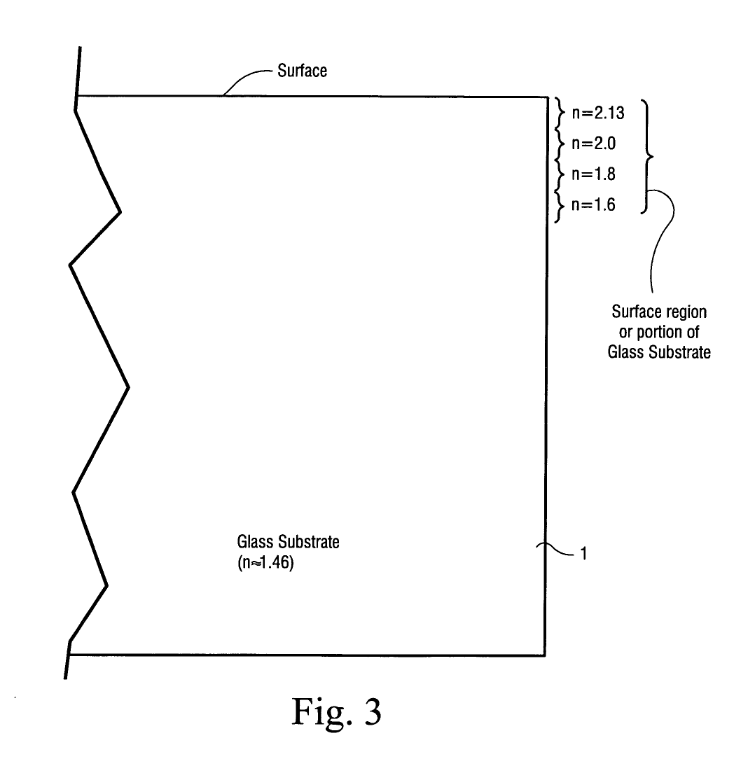

FIG. 3 is a cross sectional view of a glass substrate 1 which may optionally be used in the FIG. 1-2 embodiment of this invention (or in any other embodiment). FIG. 3 illustrates that the ion implantation of the surface region of the glass substrate 1 is performed in a manner so that the index of refraction value (n) is graded in the surface region of the glass substrate. In particular, the index value gets progressively smaller moving away from the surface of the glass substrate 1 toward the interior of the substrate. Such a refractive index gradient is advantageous in that it reduces the likelihood of, or prevents, any type of reflective interface region in the glass substrate body. This gradient may, in theory, be made up of a plurality of different thin layers each having a different refractive index value so that the index values get larger moving toward the surface of the glass substrate 1 as shown in FIG. 3. The gradient of the index variation in the surface region of the glass substrate 1 may be continuous, or may be sporadic (e.g., step-like) in different embodiments of this invention. In certain example embodiments of this invention, to create this index gradient, a plurality of different ion sources 26 may be placed in series each using a different power. In certain example embodiments of this invention, the gradient may be approximately a quarter-wave or greater in certain example embodiments of this invention.

Still referring to FIG. 3, the ion implanted region of the glass substrate may extend downwardly into the glass substrate 1 from the surface of the substrate at least about 50 Å in certain example embodiments of this invention, more preferably at least about 100 Å, even more preferably at least about 200 Å, still more preferably at least about 300 Å, and most preferably from about 500 to 600 Å. It is possible that depths of greater than 700 Å may also be useful (e.g., in situations where the index variation in the implanted region is fairly gradual). In certain example embodiments, the depth of the gradient region due to the ion implantation is at least about ¼ the wavelength of light at the design wavelength. While the index (n) varies through the gradient ion implanted region/layer, its depth can be estimated by assuming n=2 and using the quarter wave equation, I=4nd, where I is the design wavelength, n is the index of refraction, and d is the depth of the ion implanted region/layer. For a design wavelength of I=500 nm for example, the quarter wave depth is approximately 69 nm. Thus, the index change of the ion implanted region extends to at least 69 nm beneath the outer glass substrate surface. The index at the point lower than 69 nm beneath the surface is that of typical float glass (i.e., about 1.46), and gradually increased moving outwardly toward the glass surface as discussed herein due to the ion implantation. As an example, 15 eV ions may create a Gaussian depth distribution having a full width at half maximum of approximately 700 angstroms. Such energies can be useful, and can be coupled with lower energy beam(s) to populate the surface of the glass with implanted ions.

In certain example embodiments, an energy of from about 5-20 eV per ion or higher may be used, more preferably about 10 eV or higher. Moreover, in certain example embodiments of this invention, in at least part of the ion implanted surface region of the glass substrate the concentration of implanted ions may be from about 10¹⁵ to 10¹⁹ per cm², more preferably from about 10¹⁶ to 10¹⁷ atoms (or ions) per cm². In one non-limiting example, the ion beam current (C/s) may be about 2.25, the ion beam length about 3000 cm, and the ino charge (C/ion) about 1.6E-19.

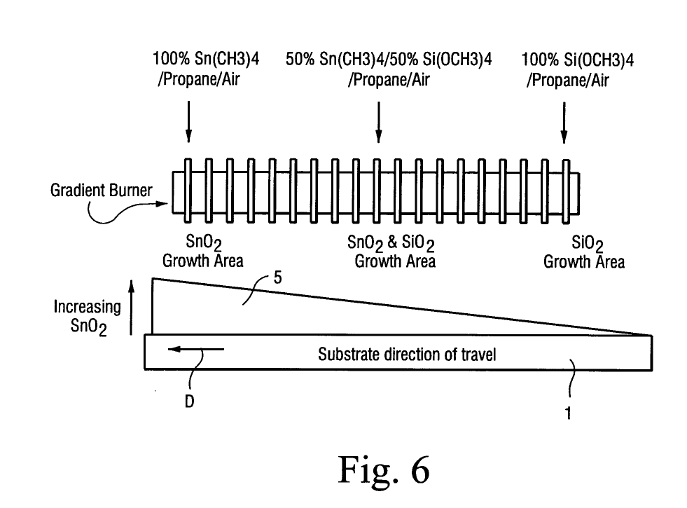

FIG. 6 is a schematic diagram of another example embodiment of this invention, which may or may not be used in combination with the FIG. 1-5 embodiments. In the FIG. 6 embodiment, an index-graded coating 5 is deposited on a surface of the glass substrate 1 by flame pyrolysis (sometimes referred to as a type of CCVD). This flame pyrolysis deposition may be done at atmospheric pressure in certain example embodiments of this invention. Different precursor gases (or gas mixture amounts) are used in different areas of the burner (or burner array) as shown in FIG. 6 so as to create a index-graded coating 5 which begins as primarily silicon oxide, changes to a substantially even mixture of silicon oxide and tin oxide, and then progresses into primarily tin oxide. Thus, it will be appreciated that the gas is graded as to content for the burner(s) over the glass substrate 1 in the FIG. 6 embodiment, so that more Sn is present in the burner (or burner array) gas further down the conveyor line than at a position upstream in the conveyor line. In a similar manner, in certain example embodiments, less Si is present in the burner gas further down the conveyor line than at a position upstream in the conveyor line. The result is a graded layer 5 of or including silicon tin oxide that is tin graded (and/or Si graded), so that more tin (and/or less Si) is located in areas further from the glass substrate than in areas of the coating 5 closer to the glass substrate 1. Thus, the index of the layer 5 is also graded from about 1.45 to 1.6 adjacent the glass substrate 1 to about 1.7 to 2.1 further or furthest from the substrate 1. Thus, the index of the graded coating 5 is higher at a position in coating 5 further from the substrate 1 than at a position in the coating closer to the substrate. The grading may be continuous or step-like in different embodiments. This graded coating 5 may be a quarter wave or thicker in certain example embodiments of this invention. This is advantageous in that it allows the outer surface of the combination of substrate 1 and coating 5 to have an index (e.g., from 1.7 to 2.3, more preferably from 2.0 to 2.2) for which an overcoat of silicon oxide will minimize reflection. Thus, an AR coating (single or multi-layer) (not shown in FIG. 6) such as of or including silicon oxide (e.g., SiO₂) and/or silicon oxynitride can be formed or deposited over index-graded coating 5. It is noted that a metal(s) other than Sn may be used in certain alternative embodiments of this invention.

With respect to flame pyrolysis, one or more burners may be used, and an array of burners may be used to achieve the graded effect discussed herein. Examples of flame pyrolysis are disclosed in, for example and without limitation, U.S. Pat. Nos. 3,883,336, 4,600,390, 4,620,988, 5,652,021, 5,958,361, and 6,387,346, the disclosures of all of which are hereby incorporated herein by reference.

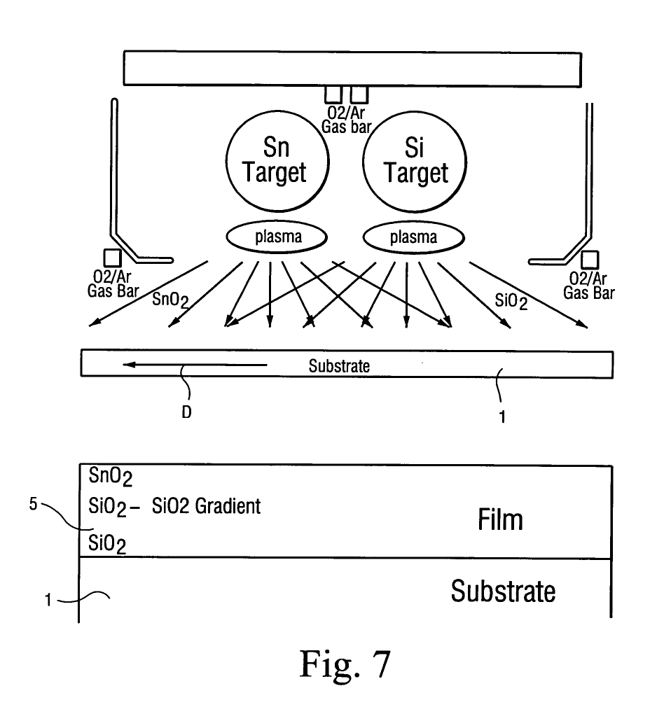

While index-graded coating 5 is deposited via flame pyrolysis in the FIG. 6 embodiment, it may instead be deposited in other manners in different embodiments of this invention. For example, graded coating 5 may be deposited via sputtering (e.g., see FIGS. 7-9), or the like, in other example embodiments of this invention.

A gradient index film or coating 5 can be grown using the magnetron sputtering process. Example methods include; codeposition, use to mixed material targets and transition from SiO₂ to Si₃N₄ deposition (e.g., see FIG. 9).

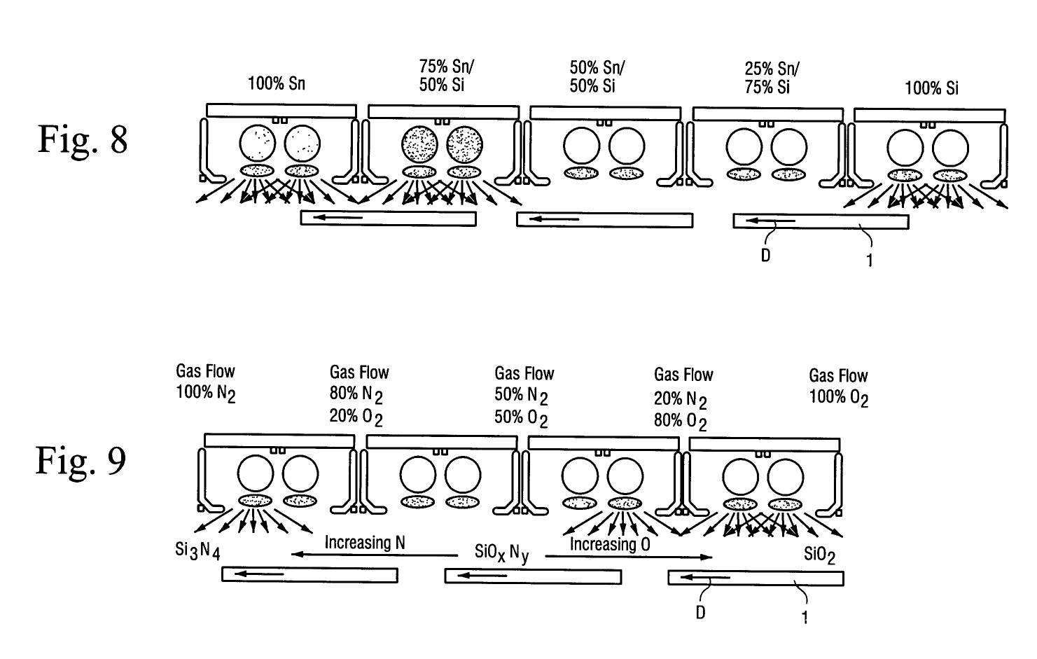

Referring to the example embodiments of FIGS. 7-8 for example, in an example codeposition process, the coater could be outfitted such that a SnO₂-doped SiO₂ film 5 could be deposited onto the glass via sputtering, wherein the composition of the layer is pure or substantially pure SiO₂ at the glass interface and the SnO₂ dopant concentration increases with distance from the glass interface. This film or coating 5 can be grown in coaters having a single bay that is outfitted with a silicon inclusive target and a tin inclusive target, as shown in FIG. 7. The film or coating 5 grown on the glass substrate 1 travelling in the direction D shown relative to the two targets can be made up of pure or substantially pure SiO₂ at the bottom and pure or substantially pure SnO₂ (or some other metal(s) oxide) at the top. The center of the film or coating 5, as illustrated in FIG. 7, can comprise a mixture of SnO₂ and SiO₂ with a concentration that tends to SiO₂ at the bottom and SnO₂ at the top. Other dopants or materials may of course bee added. In certain example embodiments, the thickness of the gradient is at least ¼ wave (e.g., 80 nm for n=1.75 and λ=550 nm).

Alternatively, as shown in FIG. 8, one could also align a bank of cathodes (magnetron sputtering targets) having varying Sn/Si ratios. The AR coating or film 5 made in the FIG. 8 embodiment would be similar to that set forth above in connection with the FIG. 7 embodiment.

Another example approach, as illustrated in FIG. 9, is to use a bank of Si cathodes (e.g., magnetron sputtering targets where the target material is Si, Si/Al or the like) to grow the varying index AR coating/film 5. In the FIG. 9 embodiment, the AR coating 5 transitions from an oxide to an oxynitride to a nitride (with minor variations be possible of course). Since this coating 5 exhibits a gradually changing oxide to nitride stoichiometry (and thus a varying index as with the other coatings 5 discussed herein), the performance may not be highly sensitive to cross ribbon stoichiometry non-uniformities. This coating could also be grown using three bays of Si targets, gaining coater flexibility at the expense of line speed. The coating 5 may also be fabricated via sol-gel, wherein two dissimilar sols are sequentially deposited, allowed to diffusion mix until the desired gradient is achieved.

Coated articles according to the embodiments discussed above may be used in the context of, for example and without limitation, storefront windows, fireplace door/window glass, picture frame glass, architectural windows, residential windows, display glass, or in any other suitable application(s). Such coated articles may have visible transmission of at least about 50%, more preferably of at least about 60%, and most preferably of at least about 70% in certain example embodiments of this invention.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

1. A method of making a coated article, the method comprising:
providing a glass substrate having an index of refraction (n) of from about 1.4 to 1.5;
implanting ions into a surface region of the glass substrate in a manner sufficient to cause an index of refraction at a surface of the glass substrate to increase to a value of from about 1.55 to 2.5, thus forming a glass substrate having a surface region that is ion implanted; and
forming an anti-reflective coating on the ion implanted surface region of the glass substrate.

2. The method of claim 1, wherein the anti-reflective coating comprises silicon oxide, and wherein the coated article has a visible transmission of at least about 60%.

3. The method of claim 1, wherein the ions comprise argon and/or nitrogen ions.

4. The method of claim 1, wherein the ions comprise nitrogen ions.

5. The method of claim 1, wherein the ions are implanted into the glass substrate to a depth of at least about 50 Å.

6. The method of claim 1, wherein the ions are implanted into the glass substrate to a depth of at least about 100 Å.

7. The method of claim 1, wherein the ions are implanted into the glass substrate to a depth of at least about 200 Å.

8. The method of claim 1, wherein the ions are implanted into the glass substrate to a depth of at least about 300 Å.

9. The method of claim 1, wherein the ion implantation is performed at a concentration of from about 10¹⁵ to 10¹⁹ atoms/cm².

10. The method of claim 1, wherein said implanting comprises implanting ions into the surface region of the glass substrate so as to cause an index of refraction at a surface of the glass substrate to increase to a value of from about 1.75 to 2.25.

11. The method of claim 1, wherein the anti-reflective coating has an index of refraction of no greater than about 1.65.

12. The method of claim 1, wherein the anti-reflective coating is in direct contact with the glass substrate.

13. The method of claim 1, wherein index of refraction changes in different locations in the ion implanted surface region, and wherein the depth of the ion implanted surface region is at least about ¼ a wavelength (I), given the following quarter wave equation:
I=4nd
where I is the wavelength, n is an index of refraction, and d is the depth in the glass substrate of the ion implanted surface region.

14. A method of making a coated article, the method comprising:
providing a glass substrate;
implanting ions into a surface region of the glass substrate, without forming a new layer on the glass substrate, in a manner sufficient to cause an index of refraction at a surface of the glass substrate to increase; and
forming an anti-reflective coating on the ion implanted surface region of the glass substrate.

15. The method of claim 14, wherein a depth of the ion implanted surface region in the glass substrate is at least about ¼ a wavelength (I), given the following quarter wave equation:
I=4nd
where I is the wavelength, n is an index of refraction, and d is the depth in the glass substrate of the ion implanted surface region.

16. A method of making a coated article, the method comprising:
providing a glass substrate;
using flame pyrolysis to form a graded layer on the glass substrate, wherein the graded layer is Si and/or Sn graded; and
forming an anti-reflective coating over the graded layer.

17. The method of claim 16, wherein the graded layer includes more Sn at a location in the graded layer further from the glass substrate than at a location in the graded layer closer to the glass substrate.

18. The method of claim 16, wherein the graded layer includes less Si at a location in the graded layer further from the glass substrate than at a location in the graded layer closer to the glass substrate.

19. The method of claim 16, wherein the flame pyrolysis is performed at atmospheric pressure.

20. A method of making a coated article, the method comprising:
providing a glass substrate;
using flame pyrolysis to form a layer on the glass substrate, wherein the layer formed using flame pyrolysis is characterized by one or more of: (a) the layer includes more of a first metal at a location in the layer further from the glass substrate than at a location in the layer closer to the glass substrate, and (b) the layer includes less Si at a location in the layer further from the glass substrate than at a location in the layer closer to the glass substrate.

21. The method of claim 20, wherein the first metal is Sn.

22. A method of making a coated article, the method comprising:
using at least first and second magnetron sputtering targets to deposit an index-graded anti-reflective film directly onto the surface of a glass substrate so as to directly contact the glass substrate;
varying the gas flows proximate the first and second targets and/or varying the materials of the first and second targets to sputter-deposit the index-graded anti-reflective film onto the surface of the glass substrate, and wherein an index of refraction of the anti-reflective film increases moving in a direction away from the glass substrate.

23. The method of claim 1, wherein the first target comprises silicon and the second target comprises tin.

24. The method of claim 1, wherein coating comprises a dielectric layer having an index of refraction value (n) which differs by no more than 0.25 from n_{c} [where n_{c}=square root of (n_{g}×nₐ), where nₐ=1.0 and n_{g} is the refractive index of an upper portion of the ion implanted surface region of the glass substrate].

25. The method of claim 1, wherein coating comprises a dielectric layer having an index of refraction value (n) which differs by no more than 0.10 from n_{c} [where n_{c}=square root of (n_{g}×nₐ), where nₐ=1.0 and n_{g} is the refractive index of an upper portion of the ion implanted surface region of the glass substrate].

26. A coated article, comprising:
a glass substrate;
a surface region of the glass substrate that is ion implanted in a manner sufficient to cause an index of refraction at a surface of the glass substrate to be from about 1.55 to 2.5, thus providing a glass substrate having a surface region that is ion implanted; and
an anti-reflective coating on the ion implanted surface region of the glass substrate.

27. The coated article claim 26, wherein coating comprises a dielectric layer having an index of refraction value (n) which differs by no more than 0.10 from n_{c} [where n_{c}=square root of (n_{g}×nₐ), where nₐ=1.0 and n_{g} is the refractive index of an upper portion of the ion implanted surface region of the glass substrate].

28. The coated article of claim 26, wherein the coated article has a visible transmission of at least about 60%.
